(19) United States
(12) Patent Application Publication
(10) Pub. No.: US 2010/0206713 A1
(43) Pub. Date: Aug. 19, 2010

(54) PZT Depositing Using Vapor Deposition

(75) Inventors: Youming Li, San Jose, CA (US); Jeffrey Birkmeyer, San Jose, CA (US)

Correspondence Address: FISH & RICHARDSON P.C., PO BOX 1022, MINNEAPOLIS, MN, 55440-1022, US

(73) Assignee: FUJIFILM Corporation

(21) Appl. No.: 12/389,078

(22) Filed: Feb. 19, 2009

(51) Int. Cl. C23C 14/34

(52) U.S. Cl. 204/192.12; 204/298.02; 204/298.13

(57) ABSTRACT

Methods and apparatus for sputtering a target material, such as PZT, can include positioning a conductive grid between a target and a substrate. The target, the substrate, and a sputtering gas can be contained in a chamber, and power of a first RF source can be applied so as to maintain a plasma in the chamber. Power of a second RF source can be applied to the conductive grid. Target material can be sputtered from the target onto the substrate. Positioning of the conductive grid and application of power by the second RF source can affect properties of sputter deposition of the target material. For example, the second RF source and the conductive grid can be part of a capacitive circuit configured such that voltage change in the capacitive circuit affects properties of the sputtering gas and, in turn, properties of a sputter deposition process.

### TECHNICAL FIELD

This description relates to depositing thin layers of material onto a substrate.

### BACKGROUND

Physical vapor deposition (PVD) is a vacuum deposition process for depositing thin films onto a substrate, such as a silicon wafer. In a PVD sputtering process, the substrate and a target formed of the material to be deposited (or precursor) on the substrate are contained in a vacuum chamber. The target is bombarded with high energy ions to vaporize the target material. The vaporized material is then transported to the substrate, and this transport is typically along a line of sight between the target and the substrate. The sputtering gas that provides the ions may be an inert gas, or may include a reactive gas, in which case chemical reactions of the target material may occur during transport. The target material (or material resulting from the reaction) condenses on a surface of the substrate to form a layer. During PVD, it can be desirable to control properties of the deposited thin film.

### SUMMARY

In one aspect, the methods and apparatus disclosed herein feature sputtering a target material, such as lead zirconium titanate oxide (PZT). A conductive grid is positioned between a target and a substrate. The target, the substrate, and a sputtering gas are contained in a chamber. Power of a first RF source is applied so as to maintain a plasma in the chamber. Power of a second RF source is applied to the conductive grid, and material can be sputtered from the target onto the substrate.

In another aspect, the methods and apparatus disclosed herein feature a chamber configured to contain a target, a substrate, and a sputtering gas. A first RF source is configured to apply power within the chamber. A conductive grid is positioned between the target and the substrate, and a second RF source is electrically connected to the conductive grid.

Implementations can include one or more of the following features. The second RF source and the conductive grid can be part of a capacitive circuit configured such that voltage change in the capacitive circuit affects properties of the sputtering gas. A distance between the conductive grid and the substrate can be adjustable and can be between about one fourth and about three fourths a distance between the target and the substrate. The second RF source can include a DC bias, and power output of the second RF source can be adjustable. The conductive grid can include lead and can include at least 90% open space. The conductive grid can be configured to substantially cover a path between the target and the substrate. A third RF source can be configured to apply power to the substrate. The sputtering gas can include oxygen, and the target can include PZT.

Implementations can provide none, some, or all of the following advantages. Adjusting a position of the conductive element, as well as an amount and frequency of RF power applied thereto, can facilitate control of the deposition process, such as by influencing properties of plasma in the deposition chamber. As another example, applying a DC bias to the conductive element and adjusting the DC bias can facilitate regulating an energy level at which target material contacts the substrate, which can further improve control of the deposition process. Improved control of the deposition process can facilitate achieving a desired target material layer on the substrate. Uniformity of target material deposition on the substrate can be improved. Thickness distribution, crystalline orientation, and internal stress of a target material layer deposited on the substrate can be controlled and improved. By applying power to plasma through the conductive element a deposition rate of the target material onto the substrate may be increased.

### DESCRIPTION OF DRAWINGS

FIG. 1A is a cross-sectional elevation view schematic representation of a deposition apparatus.

FIG. 1B is a cross-sectional plan view schematic representation of the deposition apparatus of FIG. 1A.

FIG. 2 is a cross-sectional elevation view schematic representation of an alternative deposition apparatus.

FIG. 3 is a flow diagram of a deposition process.

Like reference symbols in the various drawings indicate like elements.

### DETAILED DESCRIPTION

Deposition of a material, such as lead zirconium titanate oxide (PZT), onto a substrate, such as a silicon wafer, can be implemented in a reaction vacuum chamber. The reaction vacuum chamber can include a target containing PZT and a conductive grid positioned between the target and the substrate. The conductive grid can be capacitively coupled to a radio frequency (RF) circuit, and RF power can be applied to the grid to affect a process of depositing material onto the substrate. A DC bias can also be applied to the grid. The deposition process can be a PVD sputtering process.

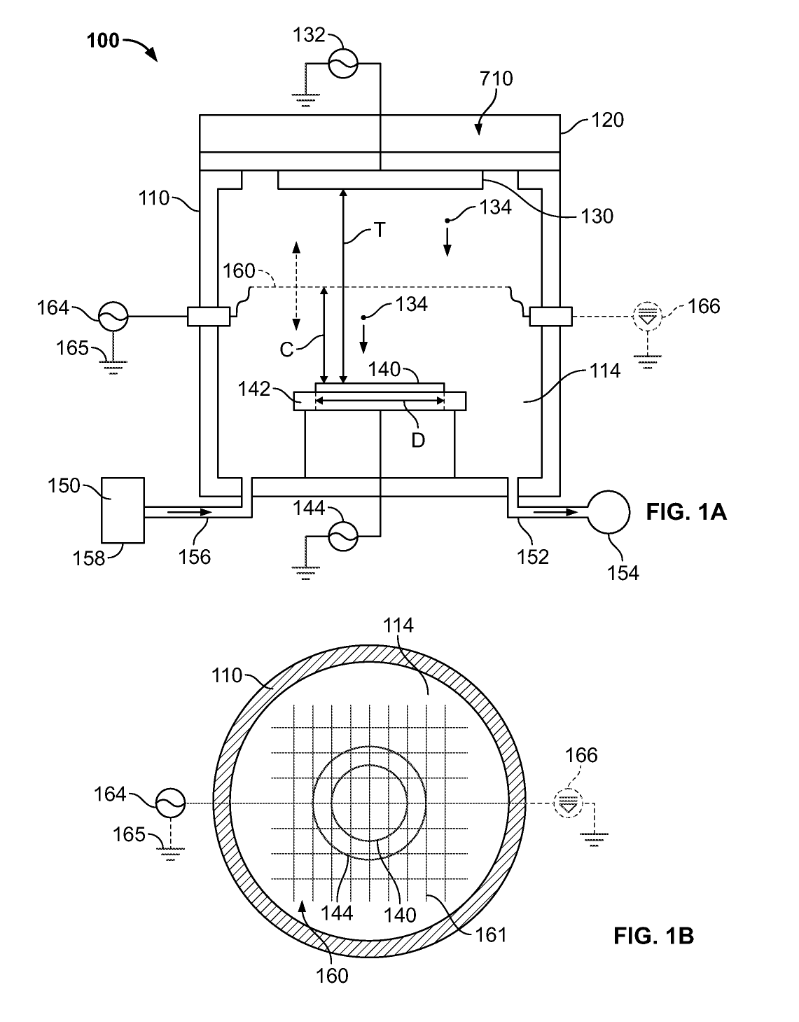

FIG. 1A is a cross-sectional elevation view of a deposition apparatus 100. A deposition chamber 110 can enclose and seal a chamber space 114. FIG. 1B is a cross-sectional plan view schematic representation of the deposition apparatus 100 of FIG. 1A. Referring to FIGS. 1A and 1B, the deposition chamber 110 can be composed and constructed sufficiently strong to resist an atmosphere of pressure (i.e., about 760 torr) as well as relatively high temperatures, such as about 500 degrees Celsius. A magnetron 120 can be attached to the deposition chamber 110 and configured to generate magnetic fields within the deposition chamber 110. The magnetron 120 can be positioned at or near an end of the deposition chamber 110.

A target 130 is positioned in the deposition chamber 110, such as at an end of the deposition chamber 110 near the magnetron 130. In some implementations, the target 130 includes PZT. An RF power source 132 can be coupled to the target 130 to apply RF voltage to induce a self-bias on the target. The RF power source can provide, for example, between about 500 watts (W) and about 5000 W, such as about 2000 W to about 4000 W, such as about 3000 W at a frequency of about 13.56 megahertz (MHz).

A substrate 140 can be positioned within the deposition chamber 110, such as within line of sight of the target 130 near an end of the deposition chamber 110 that is opposite the target 130. The substrate 140 can be a semiconductor wafer, such as a silicon wafer. As an example, the substrate 140 can have a diameter D of about 300 millimeters (mm). The substrate 140 can be supported by a substrate support 142. In some implementations, the substrate support can adjust a position of the substrate 140 in the deposition chamber 110 relative to the target 130. Optionally, the substrate 140 can be electrically connected to a substrate power source 144. In some implementations, the substrate power source 144 applies a direct current (DC) voltage bias to the substrate 140. Alternatively or in addition, the substrate power source 144 can apply RF voltage to the substrate 140.

Gas can be evacuated from the chamber space 114 through an outlet 152, which can be fluidically connected to a vacuum pump 154. A sputtering gas 150 can be introduced to the chamber space 114 by an inlet 156, which can be fluidically connected to a gas supply 158. In some implementations, the sputtering gas 150 includes both a reactive gas and an inert gas. For example, the sputtering gas 150 can include about 1% to about 4% reactive gas and the remaining sputtering gas 150 can be an inert gas. In some implementations, the reactive gas is oxygen and the inert gas is argon. The sputtering gas 150 can be present in the deposition chamber at a relatively low pressure, such as an absolute pressure of between about 2 millitorr and about 10 millitorr, and this pressure can be adjustable.

The sputtering gas 150 is ionized to produce positive ions, and the self-bias voltage on target 130 in conjunction with the magnetic field causes bombardment of the target 130 by the energetic positive ions.

The deposition apparatus 100 can also include a conductive element through which the vaporized target material can pass, such as a conductive grid 160, that can be positioned between the target 130 and the substrate 140. For example, the conductive grid 160 can be positioned midway between the target 130 and the substrate 140. Position of the conductive grid 160 relative to the target 130 and the substrate 140 can be adjustable. For example, the conductive grid 160 can be positioned at a distance G from the substrate 140 between about one fourth and about three fourths a distance T between the target 130 and the substrate 140. As an example, the distance G can be between about 20 mm and about 50 mm. The conductive grid 160 can be generally planar and parallel to the substrate. The conductive grid 160 can be, for example, a grid composed of wires 161, e.g., a wire mesh. In some implementations, an area of the conductive grid 160 can include at least about 90% open space. In some implementations, the conductive grid 160 substantially covers a path between the target 130 and the substrate 140. That is, the conductive grid 160 can be configured so that any straight, line-of-sight path between the target 130 and the substrate 140 passes through the conductive grid 160. Although some vaporized target material may be blocked by the conductive grid 160, some of the vaporized target material will pass through, e.g., between wires 161 of the conductive grid 160. In some implementations, an area spanned by the conductive grid 160 can be substantially larger than a surface area of the substrate 140.

A grid power source 164 can be electrically connected to the conductive grid 160. The grid power source 164 can be configured to apply an RF signal to the conductive grid 160. That is, for example, the grid power source 164 can apply to the conductive grid 160 an oscillating voltage with reference to a ground 165. In some implementations, the conductive grid 160 and the grid power source 164 form a predominantly capacitive circuit. That is, the grid power source 164 can cause voltage of the conductive grid 160 to vary with respect to a reference voltage while little or no current flows through the conductive grid 160. As an example, the grid power source 164 can apply about 100 W to about 500 W to the conductive grid 160 at a frequency of about 13.56 MHz. Power output of the grid power source 164 can be adjustable. Power applied to the conductive grid 160 can create a magnetic field within the deposition chamber 110. Such a magnetic field can be desirable to affect properties of plasma within the deposition chamber, and some such properties are described below. Optionally, a grid DC bias circuit 166 can also be electrically connected to the conductive grid 160 and configured to apply a DC bias thereto.

Applying power or a DC bias to the conductive grid 160 can, for example, alter properties of a plasma in the deposition chamber 110, which can affect an amount of energy of target material 134 arriving at the substrate 140. This may be desirable, for example, because target material 134 may form a thin film on the substrate more readily or more uniformly at some energy levels than at others. The power or DC bias supplied to the conductive grid 160 can be adjusted to optimize or otherwise control deposition rate, uniformity of deposition, or some other deposition property. In some implementations, the grid DC bias circuit 166 can include a capacitor (not shown), a capacitor and a resistor (not shown), or some other suitable circuit.

In some implementations, including elemental lead, e.g., substantially pure elemental lead, in the conductive grid 160 can improve deposition of PZT on the substrate 140. Lead may tend to evaporate off of the substrate 140 during a deposition process. Without being limited to any particular theory, using a conductive grid 160 that includes lead can increase a concentration of lead atoms near the substrate 140, thereby increasing an amount of lead available for formation of PZT on the substrate 140. The wires of the conductive grid can be formed entirely of lead, or a layer of substantially pure lead could be deposited as a coating on the wires of the grid. In some implementations, PZT composition on the surface of the substrate 140 can be adjusted by adjusting power or DC bias applied to the conductive grid 160 or by adjusting an amount of lead in the conductive grid 160.

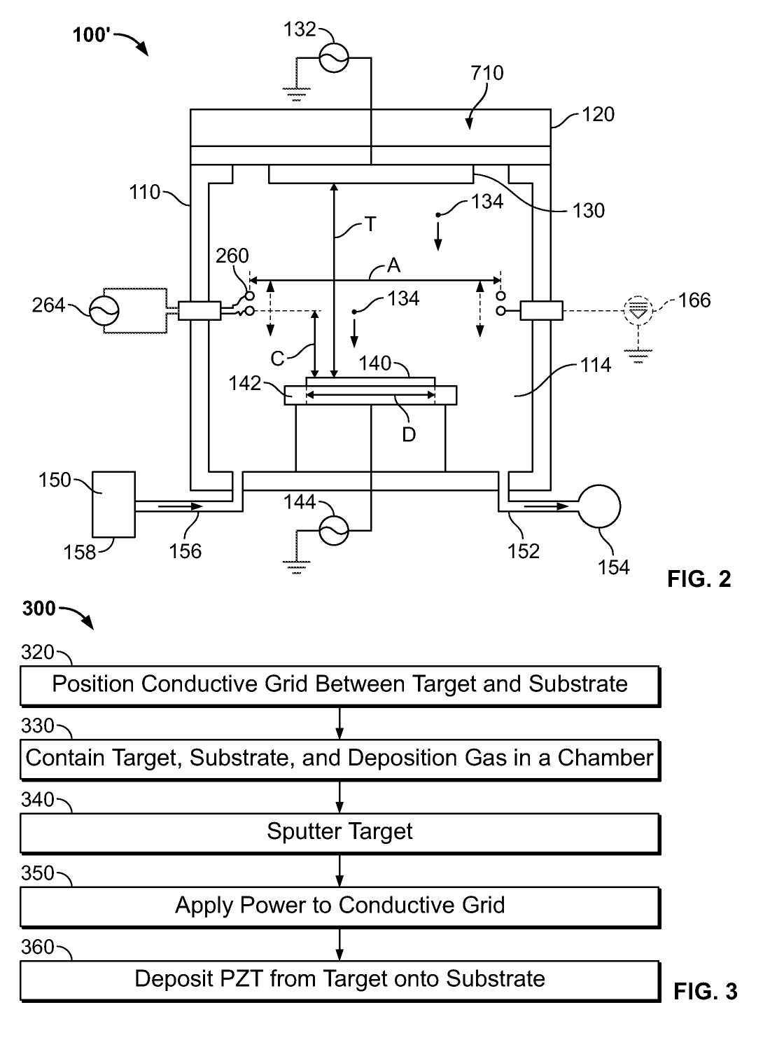

FIG. 2 is a cross-sectional elevation view of an alternative deposition apparatus 100′. A conductive coil 260 can be positioned between the target 130 and the substrate 140. As an example, the conductive coil 260 can have a diameter A of between about 300 mm and about 350 mm. Position of the conductive coil 260 relative to the target 130 and the substrate 140 can be adjustable. For example, the conductive coil 260 can be positioned at a distance C from the substrate 140 between about one fourth and about three fourths a distance T between the target 130 and the substrate 140. As an example, the distance C can be between about 20 mm and about 50 mm. In some implementations, the conductive coil 260 is electrically connected to a coil RF source 264. For example, the coil RF source 264 and the conductive coil 260 can form a predominantly inductive circuit. In such implementations, the coil RF source 264 can cause current flow through the conductive coil 260, which can induce an electromagnetic field within the deposition chamber 110. This electromagnetic field can influence properties of a plasma in the deposition chamber 110 and can influence deposition of the target material 134 on the substrate 140. In some implementations, the coil 260 is positioned inside the deposition chamber 100. In some alternative implementations, the coil 260 is positioned outside of and around the deposition chamber 110. Such implementations may be feasible where the deposition chamber 110 is composed of non-conductive materials, such as ceramics.

FIG. 3 is a flow diagram of a PVD sputtering process 300. The conductive grid 160 can be positioned between the target 130 and the substrate 140 (step 320). The target 130, the substrate 140, and the sputtering gas 150 can be contained within the deposition chamber 110 (step 330).

The target 130 can be bombarded with ions as part of a PVD sputtering process so that the target 130 releases atoms or molecules of target material 134 (step 340). For example, the sputtering gas 150 can be ionized, and the magnetic field can concentrate plasma near the target 130. Positive ions of the sputtering gas 150 can impact the target 130, and momentum transfer can cause atoms or molecules of target material 134 to be ejected from the target 130. The target material 134 can move in many or all directions away from the target 130, including toward the substrate 140 in a direction of the arrows in FIGS. 1 and 2.

RF power can be applied to the conductive grid 160 or the conductive coil 260 to affect properties of the sputtering process 300 (step 350). Deposition process properties can include, for example, density of plasma, plasma potential, sheath wide re-distribution, electron temperature, and ion flux distribution. Other deposition properties can include thickness distribution, crystalline orientation, and internal stress of material deposited on the substrate 140. Additional deposition properties can include the properties of coverage of surface protrusions and depressions and areas therebetween on the substrate 140, such as step coverage of surface topography of the substrate 140. It may be desirable to control properties of the deposition process, for example, to improve uniformity of a layer of target material 134 deposited on the substrate 140. Without being limited to any particular theory, deposition properties can be affected because power applied to the conductive grid 160 or conductive coil 260 can influence, for example, energy of target material 134 contacting the substrate 140. Applying RF power or DC bias to the conductive grid 160 or the conductive coil 260 can also be used to increase plasma density in the chamber space 114. Increasing plasma density may be desirable to increase a rate of vapor deposition.

The sputtering process 300 can be implemented to deposit PZT from the target 130 onto the substrate 140 (step 360), as described above.

The above-described implementations can provide none, some, or all of the following advantages. Adjusting a position of the conductive element, as well as an amount and frequency of RF power applied thereto, can facilitate control of the deposition process, such as by influencing properties of plasma in the deposition chamber. As another example, applying a DC bias to the conductive element and adjusting the DC bias can facilitate regulating an energy level at which target material contacts the substrate, which can further improve control of the deposition process. Improved control of the deposition process can facilitate achieving a desired target material layer on the substrate. Uniformity of target material deposition on the substrate can be improved. Thickness distribution, crystalline orientation, and internal stress of a target material layer deposited on the substrate can be controlled and improved. By applying power to plasma through the conductive element a deposition rate of the target material onto the substrate may be increased.

A number of embodiments have been described. Nevertheless, it will be understood that various modifications may be made without departing from the spirit and scope of this disclosure. For example, instead of using a grid or a coil, a conductive element in some other form can be used, such as an expanded metal mesh, a perforated foil, or some other suitable conductive element. Accordingly, other embodiments are within the scope of the following claims.

What is claimed is:

1. A method for sputtering, comprising:
positioning a conductive grid between a target and a substrate;
containing the target, the substrate, and a sputtering gas in a chamber;
applying power of a first RF source so as to maintain a plasma in the chamber;
applying power of a second RF source to the conductive grid; and
sputtering material from the target onto the substrate.

2. The method of claim 1, wherein the second RF source and the conductive grid are part of a capacitive circuit configured such that voltage change in the capacitive circuit affects properties of the sputtering gas.

3. The method of claim 1, wherein a distance between the conductive grid and the substrate is between about one fourth and about three fourths a distance between the target and the substrate.

4. The method of claim 1, wherein a distance between the conductive grid and the substrate is adjustable.

5. The method of claim 1, wherein the second RF source includes a DC bias.

6. The method of claim 1, wherein a power output of the second RF source is adjustable.

7. The method of claim 1, wherein the conductive grid includes lead.

8. The method of claim 1, wherein the conductive grid substantially covers a path between the target and the substrate.

9. The method of claim 1, wherein the conductive grid includes at least 90% open space.

10. The method of claim 1, further comprising: applying power of a third RF source to the substrate.

11. The method of claim 1, wherein the sputtering gas includes oxygen.

12. The method of claim 1, wherein the target includes PZT.

13. A vapor deposition apparatus, comprising:
a chamber configured to contain a target, a substrate, and a sputtering gas;
a first RF source configured to apply power within the chamber;
a conductive grid positionable between the target and the substrate; and
a second RF source electrically connected to the conductive grid.

14. The apparatus of claim 13, wherein the second RF source and the conductive grid are part of a capacitive circuit configured such that voltage change in the capacitive circuit affects properties of the sputtering gas.

15. The apparatus of claim 13, wherein a distance between the conductive grid and the substrate is between about one fourth and about three fourths a distance between the target and the substrate.

16. The apparatus of claim 13, wherein a distance between the conductive grid and the substrate is adjustable.

17. The apparatus of claim 13, wherein the second RF source includes a DC bias.

18. The apparatus of claim 13, wherein the conductive grid includes lead.

19. The apparatus of claim 13, wherein the conductive grid substantially covers a path between the target and the substrate.

20. The apparatus of claim 13, wherein the conductive grid includes at least 90% open space.

21. The apparatus of claim 13, further comprising:
a third RF source configured to electrically connect to the substrate.

22. The apparatus of claim 13, wherein the sputtering gas includes oxygen.

23. The apparatus of claim 13, wherein the target includes PZT.
